(19) United States
(12) Patent Application Publication
(10) Pub. No.: US 2013/0255784 A1
(43) Pub. Date: Oct. 3, 2013

(54) GAS DELIVERY SYSTEMS AND METHODS OF USE THEREOF

(71) Applicant: APPLIED MATERIALS, INC., Santa Clara, CA (US)

(72) Inventors: ZHIYUAN YE, San Jose, CA (US); BALASUBRAMANIAN RAMACHANDRAN, Santa Clara, CA (US); DENNIS DEMARS, Santa Clara, CA (US)

(73) Assignee: APPLIED MATERIALS, INC., Santa Clara, CA (US)

(21) Appl. No.: 13/789,819

(22) Filed: Mar. 8, 2013

Related U.S. Application Data
(60) Provisional application No. 61/617,826, filed on Mar. 30, 2012.

(51) Int. Cl. H01L 21/02

(52) U.S. Cl. CPC H01L 21/02
USPC 137/1; 137/561 A

(57) ABSTRACT

Gas delivery systems and methods of use thereof is provided herein. In some embodiments, a gas delivery system may include a first gas supply to provide a first gas along a first flow path; a flow divider disposed in the first flow path to divide the first flow path into a plurality of second flow paths leading to a plurality of corresponding gas delivery zones; and a plurality of second gas supplies respectively coupled to corresponding ones of the second flow paths to independently provide a second gas to respective ones of the plurality of second flow paths.

### CROSS-REFERENCE TO RELATED APPLICATIONS

This application claims benefit of U.S. provisional patent application Ser. No. 61/617,826, filed Mar. 30, 2012, which is herein incorporated by reference.

### FIELD

Embodiments of the present invention generally relate to semiconductor processing equipment.

### BACKGROUND

Conventional gas supply systems utilized to provide process gases to a process chamber often utilize carrier gases to facilitate the delivery of the process gases to the process chamber. In such systems the process gases and the carrier gas is typically mixed and provided in a single flow path, which may then be divided downstream of the process gas and carrier gas mixing point into multiple flow paths to facilitate delivery of the process gas and carrier gas to any separate gas delivery zones. However, the inventors have observed that costly equipment is required to divide the mixed gases into the multiple flow paths. Moreover, the inventors have observed that, in such systems, control over the amount of the process gas delivered to the respective gas delivery zones is limited.

Therefore, the inventors have provided an improved gas delivery system.

### SUMMARY

Gas delivery systems and methods of use thereof is provided herein. In some embodiments, a gas delivery system may include a first gas supply to provide a first gas along a first flow path; a flow divider disposed in the first flow path to divide the first flow path into a plurality of second flow paths leading to a plurality of corresponding gas delivery zones; and a plurality of second gas supplies respectively coupled to corresponding ones of the second flow paths to independently provide a second gas to respective ones of the plurality of second flow paths.

In some embodiments, a substrate processing system may include a chamber body having a substrate support for supporting a substrate disposed within an inner volume of the chamber body, the inner volume having a plurality of gas delivery zones; a first gas supply to provide a first gas to the inner volume; a flow divider disposed between the first gas supply and the chamber body to divide a flow of the first gas from the first gas supply into a plurality of flow paths fluidly coupled to respective ones of the plurality of gas delivery zones; and a plurality of second gas supplies, one each respectively coupled to corresponding flow paths of the plurality of flow paths to independently provide a second gas to the plurality of flow paths.

In some embodiments, a method of processing a substrate may include dividing a flow of a first gas from a first gas supply into a plurality of flow paths coupled to a corresponding plurality of gas delivery zones of a process chamber for processing a substrate; and providing a flow of a second gas to each of the plurality of flow paths independently of the flow of the first gas to form independently controllable mixtures of the first gas and the second gas flowing into each of the plurality of gas delivery zones.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a gas delivery apparatus in accordance with some embodiments of the present invention.

FIG. 2 is a process chamber suitable for use with the gas delivery apparatus in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of gas delivery systems are provided herein. In some embodiments, an inventive gas delivery system as described herein may advantageously facilitate the division of process gases at low flow rates, thus eliminating the need for costly high-flow flow ratio controllers. In some embodiments, an inventive gas delivery apparatus as described herein may advantageously provide substantially even flow fields across multiple gas delivery zones, thereby facilitating a uniform delivery of the combined gases across a process chamber. In some embodiments, an inventive gas delivery apparatus as described herein may advantageously facilitate independent control over a flow rate and composition of a process gas/carrier gas mixture with respect to each gas delivery zone.

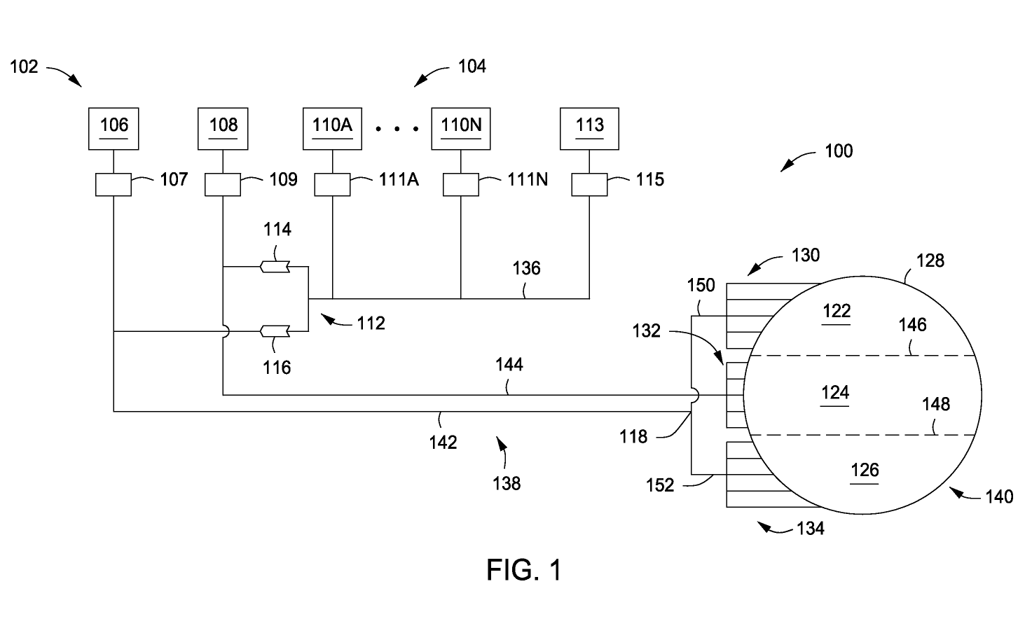

FIG. 1 depicts a schematic view of a gas delivery system 100 in accordance with some embodiments of the present invention. In some embodiments, the gas delivery system 100 may generally comprise a first gas supply 104 to provide a first gas to a first flow path 136, a flow divider 112 disposed in the first flow path 136 to divide the first flow path 136 into a plurality of second flow paths 138, and a plurality of second gas supplies 102 respectively coupled to the plurality of second flow paths 138 to independently provide a second gas to respective ones of the plurality of second flow paths 138. In some embodiments, the plurality of second gas supplies 102 are respectively coupled to the plurality of second flow paths 138 upstream of the junction with the first gas supply 104. In some embodiments, each of the plurality of second flow paths 138 may provide a mixture of the first gas and the second gas provided by the first gas supply 104 and the plurality of second gas supplies 102, respectively, to two or more gas delivery zones 140 of a process chamber 128.

The first gas supply 104 may comprise any number of gas supplies (e.g., gas supplies 110A-N shown in FIG. 1) necessary to perform a desired process in the process chamber 128. For example, in some embodiments, the first gas supply 104 may comprise one gas supply (e.g., gas supply 110A) or, in some embodiments, two or more gas supplies (e.g., gas supplies 110A-N). In embodiments where the first gas supply 104 comprises two or more gas supplies 110A-N, the gas supplies 110A-N may be part of a gas panel, or in some embodiments individually coupled to the first flow path 136, such as shown in FIG. 1. In some embodiments, each gas supply 110A-N of the first gas supply 104 may comprise a flow control mechanism 111A-N, for example, such as a flow restrictor, mass flow controller, valve, flow ratio controller, or the like, to allow control over the flow rate of each gas supplied from the gas supplies 110A-N.

The first gas may be any process gas or gas mixture suitable to perform a desired process in the process chamber 128. In some embodiments, for example where a deposition process, such as an epitaxial deposition process, is performed to deposit, for example, a Group III-V semiconductor material, the gas supplies may illustratively provide process gases comprising gallium (Ga), indium (In), arsenic (As), aluminum (Al), or the like. Other gases or gas mixtures may also be provided as desired to perform the particular process.

The second gas may be any suitable gas to be mixed with the first gas and delivered to the process chamber 128. In some embodiments, the second gas may be a carrier gas suitable for facilitating delivery of the process gases to the process chamber 128, for example, such as hydrogen (H₂), nitrogen (N₂), argon (Ar), helium (He), or the like. In some embodiments, the second gas provided by each of the plurality of second gas supplies 102 may be the same gas. Alternatively, the second gas supplied by each of the plurality of second gas supplies 102 may be a different gas.

In some embodiments, for example, such as where the first gas is provided at a low flow rate (e.g., a flow rate of less than about 2,000 sccm, or in some embodiments, about 5 to about 10 sccm), a third gas supply 113 may be disposed upstream of the first gas supply 104 to provide a third gas to the first flow path. In such embodiments, a flow control mechanism 115 (e.g., a mass flow controller, flow restrictor, or the like) may be coupled to the third gas supply 113 to facilitate control over a flow rate of the third gas. When provided, the third gas may function as a “push flow” to facilitate the movement of the first gas through the first flow path 136 towards the flow divider 112. The third gas may be any gas suitable to facilitate such movement, for example such as any of the carrier gases described above.

The inventors have observed that in conventional gas supply systems process gases, such as the process gases (i.e., the first gas) described above, are typically delivered to a process chamber via a high flow (e.g., a flow rate of greater than about 5,000, or in some embodiments, greater than about 10,000 sccm) of carrier gas (i.e., the second gas). In such systems, the process gases and the carrier gas is mixed into a single flow stream and subsequently split downstream into multiple flow paths to facilitate delivery of the mixed gases to gas delivery zones. However, the inventors have observed that splitting the flow of gas downstream of the carrier gas supply requires costly equipment (e.g., a high-flow flow ratio controller (FRC)) due to the high flow of the carrier gas necessary to facilitate delivery of the process gases, even where the flow rate of the process gas (without the carrier gas) may be low.

Accordingly, in some embodiments, the flow divider 112 may be disposed in the first flow path 136 upstream of the plurality of second gas supplies 102 to divide the first flow path 136 into the plurality of second flow paths 138. The inventors have observed that, because of the comparably low flow rate of process gas compared to the flow rate of the carrier gas, providing the flow divider 112 upstream of the plurality of second gas supplies 102 allows the first flow path 136 to be divided into the plurality of second flow paths at a low flow rate (e.g., a flow rate of less than about 2,000 sccm, or in some embodiments, less than about 3000 sccm), thereby eliminating the need for costly high-flow flow ratio controllers.

The flow divider 112 may divide the first flow path 136 into any number of second flow paths 138. For example, although only two second flow paths 138 (second flow paths 142, 144) are shown, in some embodiments, more than two second flow paths 138, for example three or more, may be utilized. The number of second flow paths 138 utilized may be determined based on factors such as physical characteristics of the process chamber 128 (e.g., size, shape, symmetry, or the like), the type of process being performed in the process chamber 128, the substrate being processed, combinations thereof, or the like. In some embodiments, a flow control mechanism 114, 116 (e.g., a flow ratio controller, mass flow controller, flow restrictor, or the like) may be coupled to each of the second flow paths 138 to independently control the amount of process gas provided by the first gas supply 104 to each of the second flow paths 138.

By providing the flow divider 112 upstream of the second gas supplies 102, and by use of the optional flow control mechanisms 114, 116, the amount of process gas provided by the first gas supply 104 to each flow path (e.g., second flow paths 142, 144) of the plurality of second flow paths 138 may be controlled independent of one another, thereby allowing for control over the concentration of the process gas within the carrier gas provided to each gas delivery zone 122, 124, 126, thus providing process flexibility and tunability.

In some embodiments, each of the plurality of second gas supplies 102 are respectively coupled to corresponding ones of the plurality of second flow paths 138 to supply the first gas (i.e., the carrier gas) to the respective second flow paths 142, 144 to facilitate delivery of the process gases provided by the first gas supply 104 to the process chamber 128. For example, as shown in FIG. 1, each of the second flow paths 142, 144 have a second gas supply 106, 108 respectively coupled thereto. In some embodiments, a flow control mechanism 107, 109, for example, such as a flow restrictor, mass flow controller, valve, flow ratio controller, or the like, may be coupled to each second gas supply 106, 108 to facilitate control over the flow rate of the carrier gas (i.e., the first gas) provided by each second gas supply 106, 108. In some embodiments, the plurality of second gas supplies 102 may be provided by a common gas supply having an output that is divided and then independently controlled in order to provide the independent plurality of second gas supplies.

The inventors have observed that by providing a second gas supply 106, 108 to each of the plurality of second flow paths 138, a flow rate of the carrier gas may be adjusted within each of the plurality of second flow paths 138 independent of one another, thereby facilitating independent adjustment of the flow field in each of the two or more gas delivery zones 140. Moreover, the inventors have further observed by providing the carrier gas to each of the plurality of second flow paths 138 separately via the plurality of second gas supplies 102, an overall flow rate of the process gas and carrier gas mixture within the plurality of second flow paths 138 may be adjusted independent of the concentration of process gas within the carrier gas (as determined by, for example, the first gas supplies 104 and/or flow control mechanisms 111A-N), thereby allowing for adjustments of the concentration of process gas within the carrier gas independent of the flow field in each of the two or more gas delivery zones 140.

Thus, gas delivery apparatus in accordance with the present invention advantageously may provide independent control of the amount of process gas (or first gas) provided to each gas delivery zone as well as the ratio of process gas to carrier gas (or second gas) in each gas delivery zone. In comparison, the inventors have observed that in conventional apparatus that split the process gas and carrier gas mixture downstream of the process gas and carrier gas mixing point, the concentration of the process gas within the carrier gas cannot be independently controlled for each gas delivery zone, thereby limiting process tunability and/or flexibility. In addition, the inventors have further observed that splitting the process gas and carrier gas mixture in such a manner may cause non-uniform flow fields within the process chamber due to a difference in flow conductance caused by different lengths of the multiple flow paths, thereby leading to a non-uniform delivery of process gases. For example, in a process chamber having three gas delivery zones (e.g., such as the gas delivery zones 122, 124, 126 of process chamber 128 described below) a flow of the process gas and carrier gas mixture may be substantially greater in outer zones (e.g., gas delivery zones 122, 126) as compared to the flow of the process gas and carrier gas mixture in an inner zone (e.g., gas delivery zone 124), thereby creating a flow field across the process chamber having a outer bias. Alternatively, the flow of the process gas and carrier gas mixture may be substantially greater in outer zones (e.g., gas delivery zones 122, 126) than in the inner zone (e.g., gas delivery zone 124), thereby creating a flow field across the process chamber having an inner bias.

The plurality of second flow paths 138 provide the combined gases (first gas provided by the first gas supplies 104 and the second gas provided by the plurality of second gas supplies 102) to the two or more gas delivery zones 140 of the process chamber 128. In some embodiments, the combined gases may be provided to the two or more gas delivery zones 140 via two or more sets of inlets (three sets of inlets 130, 132, 134 shown). As used herein, a set may include one or more inlets. In some embodiments, the two or more sets of inlets 130, 132, 134 may be coupled to a gas delivery mechanism disposed within the process chamber 128, for example, such as a showerhead, nozzles, or the like.

Although three gas delivery zones 122, 124, 126 are shown in FIG. 1, two or more gas delivery zones 140 may be utilized to provide a desired flow pattern within the process chamber 128. The number of gas delivery zones 140 may be determined based on factors such as physical characteristics of the process chamber 128 (e.g., size, shape, symmetry, or the like). For example, in some embodiments, the two or more gas delivery zones 140 may comprise an inner gas delivery zone (e.g. gas delivery zone 124) and outer gas delivery zones (e.g., gas delivery zones 122, 126), such as shown in FIG. 1.

Each flow path of the plurality of second flow paths 138 may provide the combined gases to one or more of the two or more gas delivery zones 140. For example, in some embodiments, one of the plurality of second flow paths 138 (e.g. second flow path 142) may be divided into two or more tertiary flow paths (two tertiary flow paths 150, 152 shown) via a flow divider 118 to provide the combined gases to outer gas delivery zones (e.g. gas delivery zones 122, 126) of the two or more gas delivery zones 140. In such embodiments, another flow path of the plurality of second flow paths 138 (e.g. second flow path 144) may provide the combined gases to an inner zone (e.g. gas delivery zone 124) of the two or more gas delivery zones 140. The inventors have observed that by providing the combined gases to the two or more gas delivery zones 140 in a symmetric arrangement (such as described above), a substantially even flow field across the gas delivery zones 122, 124, 126 may be produced (indicated by dotted lines 146, 148), thereby facilitating a uniform delivery of the combined gases across the process chamber 128.

Although only one gas delivery system 100 is shown in FIG. 1, it is to be understood that more than one gas delivery system 100 (e.g., two or more gas delivery systems 100) may be coupled to a process chamber (e.g., process chamber 128). Utilizing more than one gas delivery system 100 may allow for the delivery of multiple gas mixtures (e.g., incompatible or reactive gas mixtures) to the process chamber separately, thereby preventing reactions between the multiple gas mixtures prior to delivery of the multiple gas mixtures to the gas delivery zones (e.g., gas delivery zones 122, 126) of the process chamber (e.g., process chamber 128).

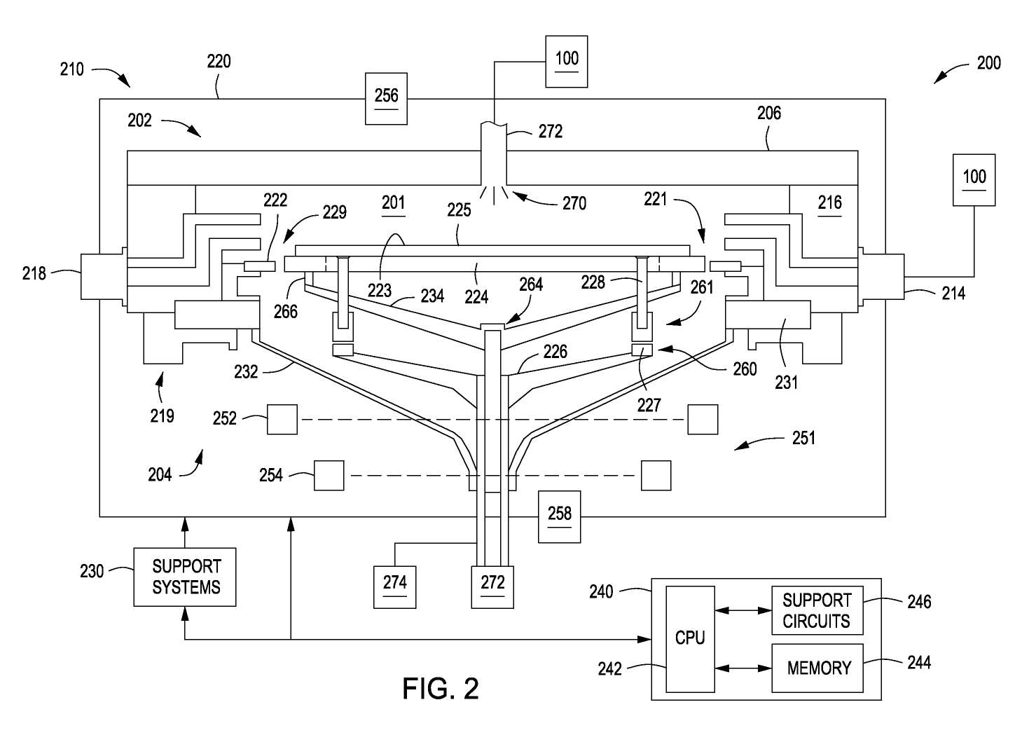

FIG. 2 depicts a schematic side view of a process chamber 200 (for example, such as the process chamber 128 described above with respect to FIG. 1) suitable for use with the inventive gas delivery system 100 in accordance with some embodiments of the present invention. In some embodiments, the process chamber 200 may be modified from a commercially available process chamber, such as the RP EPI® reactor, available from Applied Materials, Inc. of Santa Clara, Calif., or any suitable semiconductor process chamber adapted for performing epitaxial silicon deposition processes. As mentioned above, gas delivery systems in accordance with the teachings described herein may also be used in other process chambers, including those not used for epitaxial deposition.

The process chamber 200 may generally comprise a chamber body 210, a temperature-controlled reaction volume 201, an injector 214, an optional showerhead 270, and a heated exhaust manifold 218. A substrate support 224 for supporting a substrate 225 may be disposed within the temperature-controlled reaction volume 201. The process chamber 200 may further include support systems 230, and a controller 240, as discussed in more detail below.

The gas delivery system 100 may be utilized to provide one or more process gases to the process chamber via the injector 214 and/or the showerhead 270 (when present). In some embodiments a single gas delivery system 100 may be coupled to both of the injector 214 and/or the showerhead 270. Alternatively, in some embodiments, a gas delivery system 100 may be coupled to each of the injector 214 and the showerhead 270, such as shown in FIG. 2.

The injector 214 may be disposed on a first side 221 of a substrate support 224 disposed inside the chamber body 210 to provide one or more process gases to the process chamber 200, from, for example, the gas delivery system 100 discussed above. The injector 214 may have a first flow path to provide the first process gas and a second flow path to provide the second process gas independent of the first process gas.

The heated exhaust manifold 218 may be disposed to a second side 229 of the substrate support 224, opposite the injector 214, to exhaust the one or more process gases from the process chamber 200. The heated exhaust manifold 218 may include an opening that is about the same width as the diameter of the substrate 225 or larger. The heated exhaust manifold may include an adhesion reducing liner (not shown). For example, the adhesion reducing liner 217 may comprise one or more of quartz, nickel impregnated fluoropolymer, nickel dioxide, or the like.

The chamber body 210 generally includes an upper portion 202, a lower portion 204, and an enclosure 220. The upper portion 202 is disposed on the lower portion 204 and includes a chamber lid 206 and an upper chamber liner 216. In some embodiments, an upper pyrometer 256 may be provided to provide data regarding the temperature of the processing surface of the substrate during processing. Additional elements, such as a clamp ring disposed atop the chamber lid 206 and/or a baseplate on which the upper chamber liner may rest, have been omitted from FIG. 2, but may optionally be included in the process chamber 200. The chamber lid 206 may have any suitable geometry, such as flat (as illustrated) or having a dome-like shape (not shown), or other shapes, such as reverse curve lids are also contemplated. In some embodiments, the chamber lid 206 may comprise a material, such as quartz or the like. Accordingly, the chamber lid 206 may at least partially reflect energy radiated from the substrate 225 and/or from lamps disposed below the substrate support 224. In embodiments where the showerhead 270 is provided and is a separate component disposed below the lid (not shown), the showerhead 270 may comprise a material such as quartz or the like, for example, to at least partially reflect energy as discussed above.

The upper chamber liner 216 may be disposed above the injector 214 and heated exhaust manifold 218 and below the chamber lid 206. In some embodiments the upper chamber liner 216 may comprises a material, such as quartz or the like, for example, to at least partially reflect energy as discussed above. In some embodiments, the upper chamber liner 216, the chamber lid 206, and a lower chamber liner 231(discussed below) may be quartz, thereby advantageously providing a quartz envelope surrounding the substrate 225.

The lower portion 204 generally comprises a baseplate assembly 219, a lower chamber liner 231, a lower dome 232, the substrate support 224, a pre-heat ring 222, a substrate lift assembly 260, a substrate support assembly 264, a heating system 251, and a lower pyrometer 258. The heating system 251 may be disposed below the substrate support 224 to provide heat energy to the substrate support 224. The heating system 251 may comprise one or more outer lamps 252 and one or more inner lamps 254. Although the term “ring” is used to describe certain components of the process chamber, such as the pre-heat ring 222, it is contemplated that the shape of these components need not be circular and may include any shape, including but not limited to, rectangles, polygons, ovals, and the like. The lower chamber liner 231 may be disposed below the injector 214 and the heated exhaust manifold 218, for example, and above the baseplate assembly 219. The injector 214 and the heated exhaust manifold 218 are generally disposed between the upper portion 202 and the lower portion 204 and may be coupled to either or both of the upper portion 202 and the lower portion 204.

In some embodiments, when present, the showerhead 270 may be disposed above the substrate support 224 (e.g., opposing the substrate support 224) to provide one or more process gases to the processing surface 223 of the substrate 225. In some embodiments, the gas delivery system 100 may be coupled to the showerhead 270 to provide the one or more process gases to the process chamber 200 via the showerhead 270.

The showerhead 270 may be integral with the chamber lid 206 (as shown in FIG. 2), or may be a separate component. For example, the outlet 271 may be a hole bored into the chamber lid 206 and may optionally include inserts disposed through the hole bored into the chamber lid 206. Alternatively, the showerhead 270 may be a separate component disposed beneath the chamber lid 206. In some embodiments, the showerhead 270 and the chamber lid 206 may both comprise quartz, for example, to limit energy absorption from the outer and inner lamps 252, 254 or from the substrate 225 by the showerhead 270 or the chamber lid 206.

The substrate support 224 may be any suitable substrate support, such as a plate (illustrated in FIG. 2) or ring (illustrated by dotted lines in FIG. 2) to support the substrate 225 thereon. The substrate support assembly 264 generally includes a support bracket 234 having a plurality of support pins 266 coupled to the substrate support 224. The substrate lift assembly 260 comprises a substrate lift shaft 226 and a plurality of lift pin modules 261 selectively resting on respective pads 227 of the substrate lift shaft 226. In one embodiment, a lift pin module 261 comprises an optional upper portion of the lift pin 228 that is movably disposed through a first opening 262 in the substrate support 224. In operation, the substrate lift shaft 226 is moved to engage the lift pins 228. When engaged, the lift pins 228 may raise the substrate 225 above the substrate support 224 or lower the substrate 225 onto the substrate support 224.

The substrate support 224 may further include a lift mechanism 272 and a rotation mechanism 274 coupled to the substrate support assembly 264. The lift mechanism 272 can be utilized to move the substrate support 224 in a direction perpendicular to the processing surface 223 of the substrate 225. For example, the lift mechanism 272 may be used to position the substrate support 224 relative to the showerhead 270 and the injector 214. The rotation mechanism 274 can be utilized for rotating the substrate support 224 about a central axis. In operation, the lift mechanism may facilitate dynamic control of the position of the substrate 225 with respect to the flow field created by the injector 214 and/or the showerhead 270. Dynamic control of the substrate 225 position in combination with continuous rotation of the substrate 225 by the rotation mechanism 274 may be used to optimize exposure of the processing surface 223 of the substrate 225 to the flow field to optimize deposition uniformity and/or composition and minimize residue formation on the processing surface 223.

During processing, the substrate 225 is disposed on the substrate support 224. The outer and inner lamps 252, 254 are sources of infrared (IR) radiation (i.e., heat) and, in operation, generate a pre-determined temperature distribution across the substrate 225. The chamber lid 206, the upper chamber liner 216, and the lower dome 232 may be formed from quartz as discussed above; however, other IR-transparent and process compatible materials may also be used to form these components. The outer and inner lamps 252, 254 may be part of a multi-zone lamp heating apparatus to provide thermal uniformity to the backside of the substrate support 224. For example, the heating system 251 may include a plurality of heating zones, where each heating zone includes a plurality of lamps. For example, the one or more outer lamps 252 may be a first heating zone and the one or more inner lamps 254 may be a second heating zone. The outer and inner lamps 252, 254 may provide a wide thermal range of about 200 to about 900 degrees Celsius. The outer and inner lamps 252, 254 may provide a fast response control of about 5 to about 20 degrees Celsius per second. For example, the thermal range and fast response control of the outer and inner lamps 252, 254 may provide deposition uniformity on the substrate 225. Further, the lower dome 232 may be temperature controlled, for example, by active cooling, window design or the like, to further aid control of thermal uniformity on the backside of the substrate support 224, and/or on the processing surface 223 of the substrate 225.

The temperature-controlled reaction volume 201 may be formed by the chamber lid 206 by a plurality of chamber components. For example, such chamber components may include one or more of the chamber lid 206, the upper chamber liner 216, the lower chamber liner 231 and the substrate support 224. The temperature-controlled reaction volume 201 may include interior surfaces comprising quartz, such as the surfaces of any one or more of the chamber components that form the temperature-controlled reaction volume 201. The temperature-controlled reaction volume 201 may be about 20 to about 40 liters. The temperature-controlled reaction volume 201 may accommodate any suitably sized substrate, for example, such as 200 mm, 300 mm or the like. For example, in some embodiments, if the substrate 225 is about 300 mm, then the interior surfaces, for example of the upper and lower chamber liners 216, 231 may be up to about 50 mm away from the edge of the substrate 225. For example, in some embodiments, the interior surfaces, such as the upper and lower chamber liners 216, 231 may be at a distance of up to about 18% of the diameter of the substrate 225 away from the edge of the substrate 225. For example, in some embodiments, the processing surface 223 of the substrate 225 may be up to about 100 millimeters, or ranging from about 0.8 to about 1 inch from chamber lid 206

The temperature-controlled reaction volume 201 may have a varying volume, for example, the size of the temperature-controlled reaction volume 201 may shrink when the lift mechanism 272 raises the substrate support 224 closer to the chamber lid 206 and expand when the lift mechanism 272 lowers the substrate support 224 away from the chamber lid 206. The temperature-controlled reaction volume 201 may be cooled by one or more active or passive cooling components. For example, the temperature-controlled reaction volume 201 may be passively cooled by the walls of the process chamber 200, which for example, may be stainless steel or the like. For example, either separately or in combination with passive cooling, the temperature-controlled reaction volume 201 may be actively cooled, for example, by flowing a coolant about the process chamber 200. For example, the coolant may be a gas.

The support systems 230 include components used to execute and monitor pre-determined processes (e.g., growing epitaxial silicon films) in the process chamber 200. Such components generally include various sub-systems. (e.g., gas panel(s), gas distribution conduits, vacuum and exhaust sub-systems, and the like) and devices (e.g., power supplies, process control instruments, and the like) of the process chamber 200.

The controller 240 may be coupled to the process chamber 200 and support systems 230, directly (as shown in FIG. 2) or, alternatively, via computers (or controllers) associated with the process chamber and/or the support systems. The controller 240 may be one of any form of general-purpose computer processor that can be used in an industrial setting for controlling various chambers and sub-processors. The memory, or computer-readable medium, 244 of the CPU 242 may be one or more of readily available memory such as random access memory (RAM), read only memory (ROM), floppy disk, hard disk, or any other form of digital storage, local or remote. The support circuits 246 are coupled to the CPU 242 for supporting the processor in a conventional manner. These circuits include cache, power supplies, clock circuits, input/output circuitry and subsystems, and the like.

Thus, a gas delivery system and methods of use thereof has been provided herein. In some embodiments, the inventive gas delivery system may advantageously provide a flow divider upstream of a high flow carrier gas supplies, thereby allowing for the division of process gases at a low flow rate, thus eliminating the need for costly high-flow flow ratio controllers. In some embodiments, the inventive gas delivery apparatus may advantageously provide process gases to two or more gas delivery zones disposed in a symmetric arrangement, thereby providing a substantially even flow field across the gas delivery zones, thus thereby facilitating a uniform delivery of the combined gases across a process chamber. In some embodiments, the inventive gas delivery apparatus may advantageously provide a carrier gas to each of a plurality of flow paths separately, thereby allowing a flow rate of the carrier gas to be independently adjusted with respect to the other flow paths. Moreover, by providing a carrier gas to each of a plurality of flow paths separately, the inventive gas delivery apparatus may further advantageously allow an overall flow rate of the process gas and carrier gas mixture within each flow path to be adjusted independent of the concentration of process gas within the carrier gas, thereby allowing for adjustments of a flow field in a process chamber independent of the concentration of process gas within the carrier gas.

While the foregoing is directed to embodiments of the present invention, other and further embodiments of the invention may be devised without departing from the basic scope thereof.

1. A gas delivery system, comprising:
a first gas supply to provide a first gas along a first flow path;
a flow divider disposed in the first flow path to divide the first flow path into a plurality of second flow paths leading to a plurality of corresponding gas delivery zones; and
a plurality of second gas supplies respectively coupled to corresponding ones of the second flow paths to independently provide a second gas to respective ones of the plurality of second flow paths.

2. The gas delivery system of claim 1, wherein the plurality of second flow paths are coupled to a plurality of gas delivery zones to provide the first gas and the second gas to the plurality of gas delivery zones.

3. The gas delivery system of claim 2, wherein each of the plurality of second flow paths provide the first gas and the second gas to the plurality of gas delivery zones via a plurality of inlets.

4. The gas delivery system of claim 3, wherein the plurality of inlets are coupled to gas injections nozzles or a showerhead.

5. The gas delivery system of claim 2, wherein the plurality of gas delivery zones are gas delivery zones of a process chamber.

6. The gas delivery system of claim 5, wherein the plurality of gas delivery zones comprise an inner gas delivery zone and two outer gas delivery zones, wherein each of the two outer gas delivery zones are disposed proximate opposing sides of the inner gas delivery zone and adjacent to the inner gas delivery zone

7. The gas delivery system of claim 6, wherein the plurality of second flow paths comprise two second flow paths, and wherein one of the two second flow paths is coupled to the inner gas delivery zone and another one of the two second flow paths is coupled to the two outer gas delivery zones.

8. The gas delivery system of claim 1, wherein the first gas is a process gas and the second gas is a carrier gas.

9. The gas delivery system of claim 1, further comprising:
a flow ratio controller coupled to each of the plurality of second flow paths to control an amount of the first gas provided to each of the plurality of second flow paths.

10. The gas delivery system of claim 1, further comprising:
a flow controller coupled to at least one of the first gas supply or the plurality of second gas supplies to control a flow rate of at least one of the first gas and second gas.

11. A substrate processing system, comprising:
a chamber body having a substrate support for supporting a substrate disposed within an inner volume of the chamber body, the inner volume having a plurality of gas delivery zones;
a first gas supply to provide a first gas to the inner volume;
a flow divider disposed between the first gas supply and the chamber body to divide a flow of the first gas from the first gas supply into a plurality of flow paths fluidly coupled to respective ones of the plurality of gas delivery zones; and
a plurality of second gas supplies, one each respectively coupled to corresponding flow paths of the plurality of flow paths to independently provide a second gas to the plurality of flow paths.

12. The substrate processing system of claim 11, wherein each of the plurality of flow paths provide the first gas and the second gas to the plurality of gas delivery zones via a plurality of inlets.

13. The substrate processing system of claim 12, wherein the plurality of inlets are coupled to gas injections nozzles or a showerhead disposed within the inner volume of the process chamber.

14. The substrate processing system of claim 11, wherein the plurality of gas delivery zones comprise an inner gas delivery zone and two outer gas delivery zones, wherein each of the two outer gas delivery zones are disposed proximate opposing sides of the inner gas delivery zone and adjacent to the inner gas delivery zone

15. The substrate processing system of claim 14, wherein the plurality of flow paths comprise two flow paths, and wherein one of the two flow paths is coupled to the inner gas delivery zone and another one of the two flow paths is coupled to the two outer gas delivery zones.

16. The substrate processing system of claim 11, wherein the first gas is a process gas and the second gas is a carrier gas.

17. The substrate processing system of claim 11, further comprising:
a flow ratio controller coupled to each of the plurality of flow paths to control an amount of the first gas provided to each of the plurality of flow paths.

18. The substrate processing system of claim 11, further comprising:
a flow controller coupled to at least one of the first gas supply or the plurality of second gas supplies to control a flow rate of at least one of the first gas and second gas.

19. A method of processing a substrate, comprising:
dividing a flow of a first gas from a first gas supply into a plurality of flow paths coupled to a corresponding plurality of gas delivery zones of a process chamber for processing a substrate; and
providing a flow of a second gas to each of the plurality of flow paths independently of the flow of the first gas to form independently controllable mixtures of the first gas and the second gas flowing into each of the plurality of gas delivery zones.

20. The method of claim 19, wherein the first gas is a process gas and the second gas is a carrier gas.
